(19) United States
(12) Patent Application Publication
(10) Pub. No.: US 2007/0134866 A1
(43) Pub. Date: Jun. 14, 2007

(54) Method for integrating carbon nanotube with CMOS chip into array-type microsensor

(75) Inventors: Jung-Tang Huang, Taipei (TW); Cheng-Hung Tsai, Taipei (TW)

Correspondence Address: Jung-Tang Huang, 5F., No.7, Lane 10, Sec. 2,, Bade Rd., Da-an District, Taipei City, 106, TW

(73) Assignee: Jung-Tang Huang

(21) Appl. No.: 11/633,255

(22) Filed: Dec. 5, 2006

(30) Foreign Application Priority Data
Dec. 13, 2005 (TW) 094144036

(51) Int. Cl. H01L 21/8238

(52) U.S. Cl. 438/199

(57) ABSTRACT

The invention disclosed a method for integrating CMOS circuit chips with carbon nanotubes (CNTs) into array-type sensors with signal processors enclosed. The method provides low-temperature and wafer-level fabrication processes including dripped a drop of dispersed CNTs solution on the top of CMOS chip, use micro probe card to contact with pairs of pads, with a function generator to generate dielectrophoresis (DEP) signal and with a lock-in amplifier to measure impedance value simultaneously. According to the impedance measurement it can detect the number of CNTs fixed on pair of pads. Only if the number of CNTs on the top of pair of pads were not expected, it would readjust the frequency of alternating current to the range of negative DEP force and repel CNTs from the top of pair of pads. Repeat positive DEP signal to attach CNTs until the number of CNTs as demand, then hold the DEP force until CNTs solution evaporated to make a well-contact between CNTs and pads. Furthermore, the surface of CNTs can be functionalized and let CNTs have high sensitivity to ambient molecules (Gas molecules, Bio molecules, et al.), then transfer the measured signal into signal processors of CMOS chips, the processors could be impedance measurement unit, current measurement unit, conductance measurement unit et. al., and it can measure, record and analyze the data of small varied signal directly.

### BACKGROUND

1. Field of Invention

This invention relates to a method and application for integrating carbon nanotube with COMS chip into sensor device, it specifically relates to a wafer level manufacturing method in low temperature to fix carbon nanotube on prepared exposed metal layer at the passivation opening of pre-designed at the CMOS circuit component.

2. Description of Related Art

In recent years, many research institutes get involved with related researches of electronic devices based on carbon nanotube, the results of these researches show that carbon nanotube electronic device has the characteristic of Ballistic Transportation, single carbon nanotube channel can resist current of ˜25 μA (Ali Javey, Jing Guo, Qian Wang, Mark Lundstrom & Hongjie Dai. “Ballistic carbon nanotube field-effect transistors”. Nature, Vol. 424, No. 39, p. 654-657, August, 2003), these superior transistor characteristics made them be able to replace current CMOS chip and become the electronic device of the next generation. Additionally, carbon nanotube electronic device can also be used to detect the foreign molecules in the environment (gas molecule, biological molecule, etc.) (Alexander Star, Tzong-Ru Han, vikram Joshi, Jean-Christophe P, and Geroge Grüner. “Nanoelectronic Carbon Dioxide Sensors”. Advanced Materials, 2004, 16, No. 22, November), (Robert J. Chen, Sarunya Bangsaruntip, et al. “Noncovalent functionalization of carbon nanotubes for highly specific electronic biosensors”. PNAS (Proceeding of the National Academy of Science), Vol. 100, p. 4984-4989, April, 2003), it owns detecting capability of high sensitivity, moreover, the volume and power consumption of the detector can be greatly reduced, and through specific surface modification on carbon nanotube, it can be used as sensor device of high sensitivity and high specific detection. From the above introduction, we know that electronic device based on carbon nanotube is going to become potential transistor and sensor device in the future.

Pioneer in the research field of carbon nanotube, Phaedon Avouris of IBM Watson Research Center, proposed in 2001 in NanoLetters a method to prepare a electronic device having capability to process logic computation through the use of carbon nanotube electronic device, it was pointed out that this electronic device can replace one important element inside the current transistor, moreover, since carbon nanotube can reach the speed of Ballistic Transportation, it can be used to execute the function of electronic transport (V. Derycke, R. Martel, J. Appenzeller, and Ph. Avouris. “Carbon Nanotube Inter- and Intramolecular Logic Gates”. NanoLetters, Vol. 1, No. 9, p. 453-456, September, 2001), this is a big breakthrough in the development of carbon nanotube electronic device, it builds a milestone that carbon nanotube electronic device can be used as a computational logic device. Although many researches show that carbon nanotube transistor intrinsically owns great development potential, however, it is still a long way to go for the implementation of research project to let carbon nanotube fully replace the current CMOS chip, moreover, based simply on these research results, it is impossible to integrate and prepare carbon nanotube electronic device into a chip unit possessing a complete function as that of CMOS; moreover, if we take a look at the process method used by IBM, it is a method that disperses the carbon nanotube prepared by laser ablation method on a pre-made electrode, we thus can conclude that it is still a great challenge to make this device reach stable process and mass production as that of CMOS device. Therefore, how to effectively integrate carbon nanotube with current CMOS chip together is really an important and potential technology.

Additionally, professor Hongjie Dai in Stanford University, USA proposed in 1998 in Nature magazine a method using Chemical Vapor Deposition (CVD) to successfully grow single-walled carbon nanotube on silicon wafer (Jing Kong, Hyongsok T. Soh, Alan Cassell, Calvin F. Quate and Hongjie Dai. “Synthesis of Individual Single-Walled Carbon Nanotubes on Patterned Silicon Wafers”. Nature, Vol. 395, p. 878-881, 1998.). After that, CVD growth of carbon nanotube on silicon wafer almost becomes the mainstream in each related lab, however, the temperature of the growth of carbon nanotube by CVD is usually in the range of 700˜1200° C., since metal layer and metal interconnection are contained in CMOS device, therefore, in the post process, only a temperature of 400° C. can be resisted, even the method proposed by professor Shigeo Maruyama in Japan in 2002 in the journal of Chemical Physics Letters through the use of low temperature alcohol CVD to synthesize carbon nanotube (the growth temperature of carbon nanotube is about 550° C.)(Shigeo Maruyama, Ryosuke Kojima, Yuhei Miyauchi, Shohei Chiashi, Masamichi Kohno. “Low-temperature synthesis of high-purity single-walled carbon nanotubes from alcohol”. Chem. Phys. Letters, Vol. 360, p. 229-234, July, 2002), or the low temperature Plasma Enhanced Chemical Vapor Deposition (PECVD) method proposed by Hongjie Dai of Stanford University in 2004 in NanoLetters to grow carbon nanotube (carbon nanotube has a growth temperature of about 600° C.)(Li, Y M; Mann, D; Rolandi, M; Kim, W; Ural, A; Hung, S; Javey, A; Cao, J; Wang, D W; Hongjie Dai, et. al. “Preferential growth of semiconducting single-walled carbon nanotubes by a plasma enhanced CVD method”. NanoLetters, Vol. 4, No. 2, p. 317-321, February, 2004), are all much higher than 400° C. which CMOS can resist in post process, therefore, the growth of carbon nanotube on silicon wafer through these methods all can not be integrated with the current COMS chip.

In 2003, professor Hongjie Dai of Stanford University announced a successful preparation of MOS structure integrated circuit chip in combination with carbon nanotube (Yu-Chih Tseng; Peiqi Xuan; Javey, A.; Malloy, R.; Qiang Wang; Bokor, J.; Hongjie Dai, “Monolithic integration of carbon nanotube devices with silicon MOS technology”. NanoLetters, Vol. 4, No. 1, p. 123-127, January, 2004), although expected purpose has been reached in the study, however, Poly is still used in the study as the interconnection and major conductor structure of MOS, such interconnection and conductor structure can resist high temperature CVD growth of carbon nanotube without getting destroyed, however, CMOS structure using metallic interconnection can not keep complete structure and characteristics after high temperature CVD growth.

To summarize the above descriptions, we know that we need one more invention: a method for integrating carbon nanotube with CMOS integrated circuit chip into molecular level sensor array system having signal processing circuit, moreover, low temperature wafer level assembly method can be used to effectively and in large scale fix carbon nanotube onto the exposed metal layer on the pre-designed opening of passivation layer of the CMOS so that when carbon nanotube senses foreign molecules, the generated tiny signals can be sent directly into the internal signal processing circuit of CMOS, and a more accurate and faster detector array chip is thus achieved.

### SUMMARY

The present invention provides a post process which will not destroy the electronic devices on the CMOS, it can effectively and sequentially fix carbon nanotube stably on the exposed metal layer of the pre-designed passivation layer opening of CMOS.

The present invention also provides for a method to effectively combine carbon nanotube to current CMOS chip, it takes advantage of CMOS circuit superiority, plus sensor device of carbon nanotube to achieve molecular level sensor system chip.

The present invention also provides for a method using probe card means to achieve Wafer-Level manufacturing and assembly so that the chip can be in mass production and the production cost can be greatly reduced.

The present invention also provides a method so that when carbon nanotube is fixed on CMOS device, an impedance measurement equipment is used in the same time to measure at any time the impedance value and to detect the quantity of carbon nanotube fixed on the electrode.

The present invention also provides a method of using the concept of Positive DEP and Negative DEP so that the extra or non-target quantity of carbon nanotube on the electrode is adjusted through the frequency of AC alternating current and is removed through Negative DEP. Then a new signal application period is executed again until the required carbon nanotube quantity is reached, then the DEP force is maintained until the dielectric solution is evaporated, through this method, carbon nanotube quantity fixed on the electrode can be precisely controlled.

The present invention also provides a method that carbon nanotube only needs to be modified on specific corresponding molecule so that it can become a versatile sensor system chip of biological molecule and gas molecule.

The present invention also provides a method that externally added measurement circuit is not necessary and the signal change generated by carbon nanotube due to foreign molecules can be sent directly into CMOS circuit for computation so that the noise and signal loss due to externally connected circuit can be alleviated.

The present invention also provides a sensor system array chip so that a small area CMOS chip can own in the same time multiple sensor unit which can process signal simultaneously, therefore, the detection time can be greatly reduced.

Therefore, a low temperature method which can be used to effectively and in large scale fix carbon nanotube onto the exposed metal layer on the pre-designed opening of passivation layer of the CMOS is proposed in the present invention. In order to fix carbon nanotube on the metal layer, first, small amount of pre-acquired and separated single-walled or multiple-walled carbon nanotube is taken and immersed into DI water solution containing 1-wt % Sodium Dodecylsulfate to let carbon nanotube wall be coated by SDS molecule, moreover, the concentration of carbon nanotube should be diluted to transparency and 0.35-wt % EthyleneDiamineTetraAcetic Acid (EDTA) and 4-vol % TRIS-HCl buffer should be added so that residual transition metal ion is compounded and stable solution PH value is maintained. First, ultrasonic vibration is used to separate and disperse uniformly the bundle-like carbon nanotube, then use centrifugal equipment to let bundle-like carbon nanotube with SDS molecules coated on the outside of the walls and impurity precipitated on the bottom, and let single carbon nanotube of lighter weight with SDS molecule coated on the outside of the wall be centrifuged to the upper part of the container, then take the 30%˜80% solution on the upper part of the solution and use these carbon nanotubes for further manipulation and fixing. Please refer to: (Zhi-Bin Zhang, Xian-Jie Liu, Eleanor E. B. Campbell, Shi-Li Zhang. “Alternating current dielectrophoresis of carbon nanotubes”. J. Appl. Phys., Vol. 98, 056103, 2005), we can be sure that the treatment of carbon nanotube solution through the above mentioned methods, it not only facilitates later manipulation of carbon nanotube by Dielectrophoresis (DEP) force, but also there is a great chance of success that only single carbon nanotube is manipulated and fixed on the pad. Additionally, since semiconductor type carbon nanotube owns a dielectric condition of Negative DEP force, this is advantageous to the application of carbon nanotube fixing (Ralph Krupke, Frank Hennrich, et. al. “Separation of Metallic from semiconducting Single-Walled Carbon Nanotubes”. Science, Vol. 301, p. 344-347, July, 2003). Put a few drops of solution containing carbon nanotube on the exposed metal pad above CMOS structure, then apply DEP force to manipulate carbon nanotube, the DEP force of carbon nanotube is manipulated through the adjustment of AC frequency, AC voltage (Peak-to-Peak voltage) and DC voltage, moreover, impedance measurement equipment is added at the same time DEP force is applied. We use a lock-in amplifier which when DEP signal is applied, the impedance measurement can be performed in the same time. It can measure the impedance value at any time and detect the quantity of carbon nanotube fixed on the electrode; additionally, through the use of the concept of Positive DEP and Negative DEP, the extra or non-target quantity of carbon nanotube on the electrode is adjusted through the frequency of AC alternating current, AC voltage (Peak-to-Peak voltage) and DC voltage and is removed through Negative DEP. Then a new signal application period is executed again, signal frequency in the positive DEP force range is applied, until the required carbon nanotube quantity is reached, then the DEP force is maintained until the dielectric solution is evaporated and N2 is blown in to dry out the residual water beads on the surface. Therefore, by using this method, low temperature post process can be used to fix carbon nanotube onto CMOS chip, CMOS device damage caused by high temperature problem as mentioned before thus will not happen, and the quantity of carbon nanotube combined on the electrode can thus be controlled more effectively and precisely, and the final goal of system type chip processing unit by integrating carbon nanotube on CMOS structure can thus be achieved.

### BRIEF DESCRIPTION OF DRAWINGS

The invention may best be understood by reference to the following description taken in conjunction with the accompanying drawings that illustrate specific embodiments of the present invention.

FIG. 1 shows an illustration of impedance type molecular detector using CMOS in association with carbon nanotube for the present invention.

FIG. 2(a) illustrates in liquid a transistor type molecule detector of the present invention using CMOS in association with carbon nanotube.

FIG. 2(b) illustrates in liquid a transistor type molecule detector of the present invention using MIM (Metal-Insulator-Metal) structure of CMOS in association with carbon nanotube.

FIG. 3 shows the wafer level method used in the present invention for the manufacturing of array type molecule sensor device containing internal circuit.

FIG. 4(a) shows the entire construction and assembly using micro probe card as tool for the application of DEP signal and using probe card for the measurement of carbon nanotube quantity and impedance value for the present invention.

FIG. 4(b) shows the detailed illustration of using micro probe card as tool for the application of DEP signal and using probe card with carbon nanotube for the measurement of carbon nanotube quantity and impedance value for the present invention.

FIG. 5 illustrates the electrode of the present invention using focused ion beam (FIB) and electron beam system to add tip-like metal in the front end of electrode above CMOS so as to facilitate the control of single carbon nanotube through DEP force.

FIG. 6 illustrates the contact between carbon nanotube and metal when post process is used to deposit Pd metal on the electrode above CMOS.

FIG. 7 shows the preparation of an entire CMOS carbon nanotube detector system chip.

FIG. 8 shows the circuit detail of voltage-current (shunt-shunt) of a feedback type trans-impedance amplifier.

FIG. 9(a) shows the output voltage waveform when input to electrical current measurement chip is a current of sine wave of 500 nA and 10 MHz.

FIG. 9(b) shows the output voltage waveform when input to electrical current measurement chip is a current of sine wave of 25 nA and 10 MHz.

### DETAILED DESCRIPTION

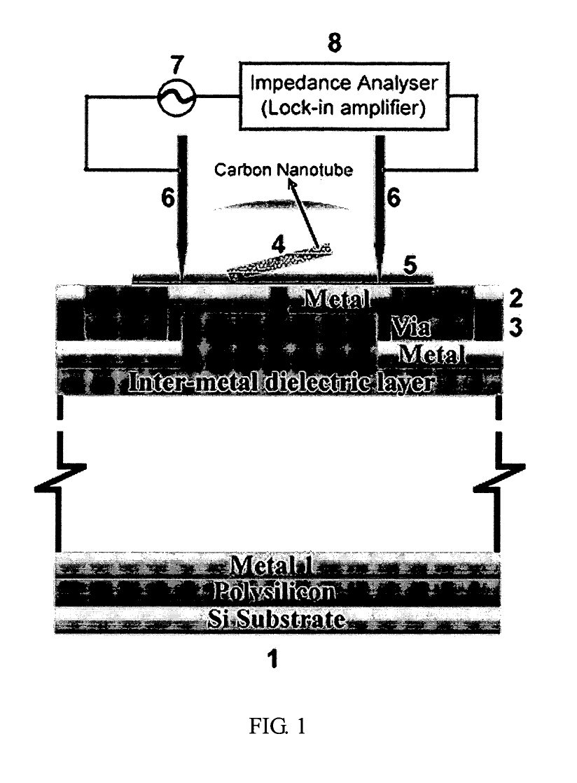

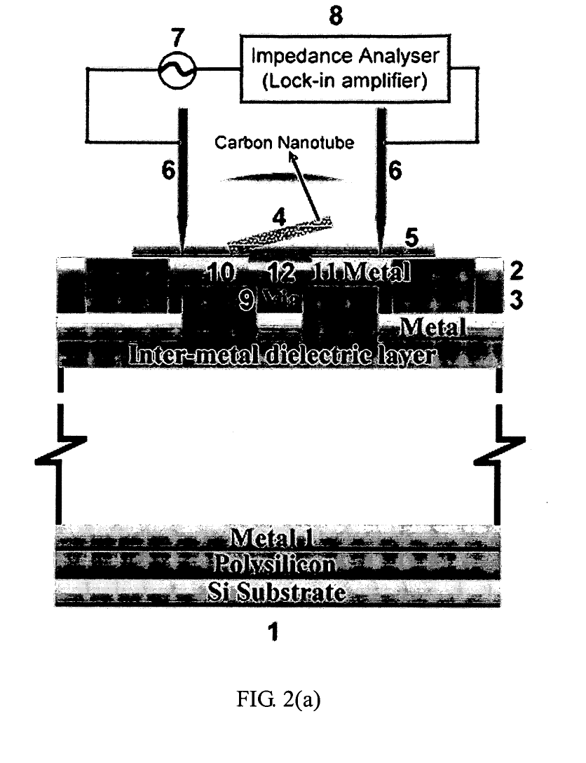

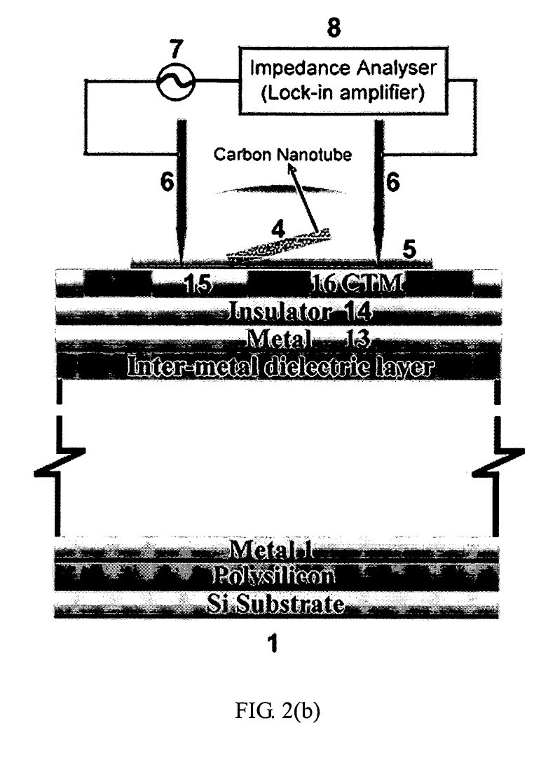

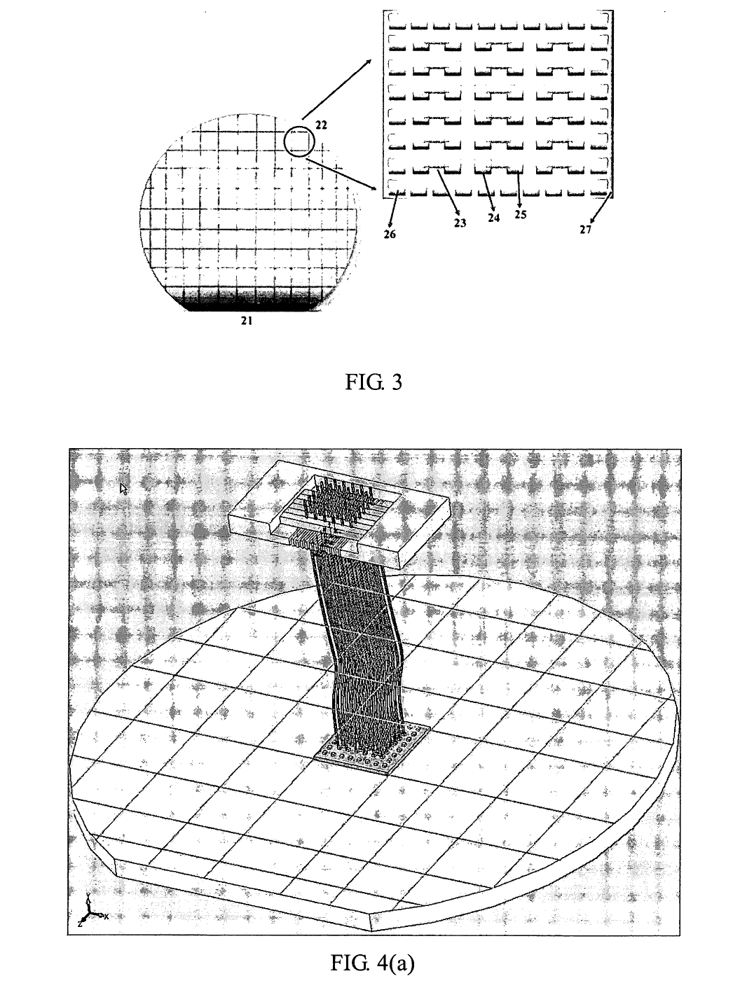

In the present invention, CMOS technology available nowadays is used, process structure provided by TSMC (for example, 0.35 cm or 0.18 μm Mixed Signal 1P6M+MIM Salicide 1.8V/3.3V) is adopted. Electronic circuit is first made through the use of CMOS process, then use DEP force to fix carbon nanotube effectively and sequentially onto the exposed metal 2. A better embodiment proposed in the present invention includes two types of CMOS carbon nanotube detector system chips: “Impedance type measurement system chip” and “transistor type system chip”, they are shown respectively as in FIG. 1 and FIG. 2. In “Impedance type measurement system chip” (FIG. 1), a pre-designed CMOS impedance measurement circuit is used to judge directly the measured impedance change. In “transistor type measurement system chip” (FIG. 2), based on different CMOS processes used, two methods for the embodiment of transistor type measurement system chip are proposed, in one of the design, via is used as back gate 9 and metal on the topmost part is used as source gate 10 and drain gate 11, through the use of post process, the passivation above via is removed to form dent 12, then put a few drops test solution containing biological molecules, based on the concept of the formation of Liquid-Gate by the solution, to control the carrier in the channel of carbon nanotube, this is as shown in FIG. 2(a); in another design, the MIM (Metal-Insulator-Metal) process provided by CMOS is used for the embodiment of transistor, since this process provides thinner insulator dielectric layer 14 (Insulator, about 38 nm thick), therefore, the design that metal at the bottom of MIM structure is used as bottom gate 13 will facilitate the control of carrier flow within carbon nanotube channel, meanwhile, the metal layer and CTM layer on top of insulator dielectric layer of MIM structure are designed as source 15 and drain 16, this is as shown in FIG. 2(b). CMOS carbon nanotube detector system chip can also be of array type, that is, each carbon nanotube detection device will include one signal processing circuit, this is as in FIG. 3, which is an illustration of wafer area array chip, we can see that each wafer area include several sensor chips and each sensor chip is equipped with one set of signal processing circuit, the detection speed can thus be greatly enhanced and multiple molecules can be detected.

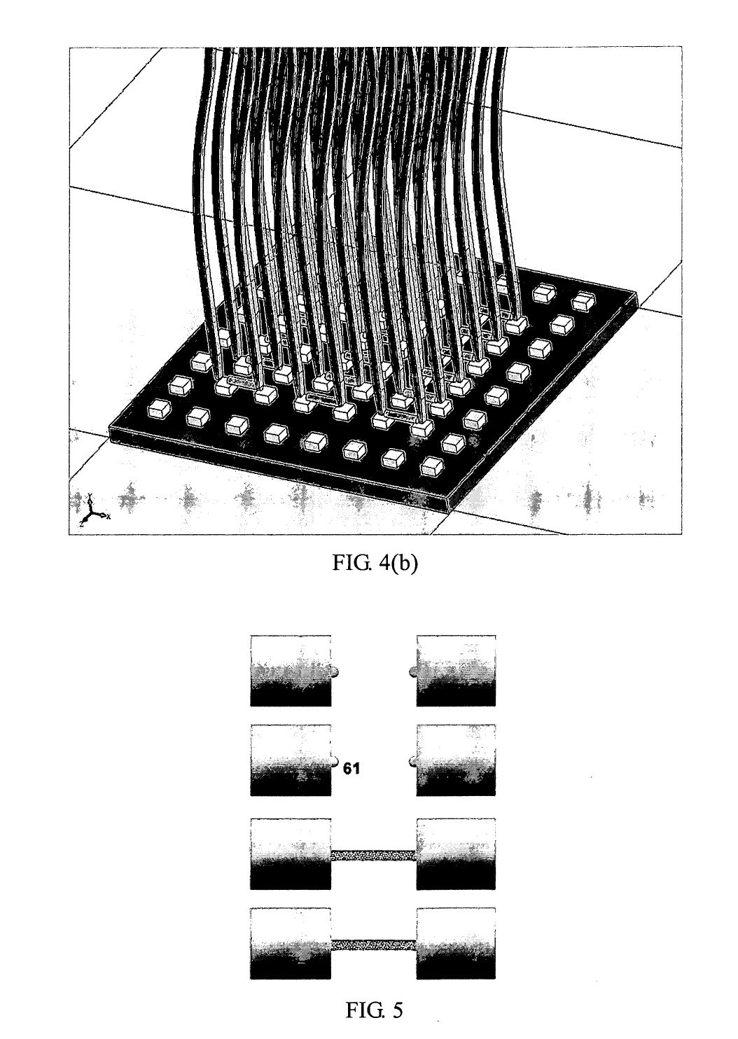

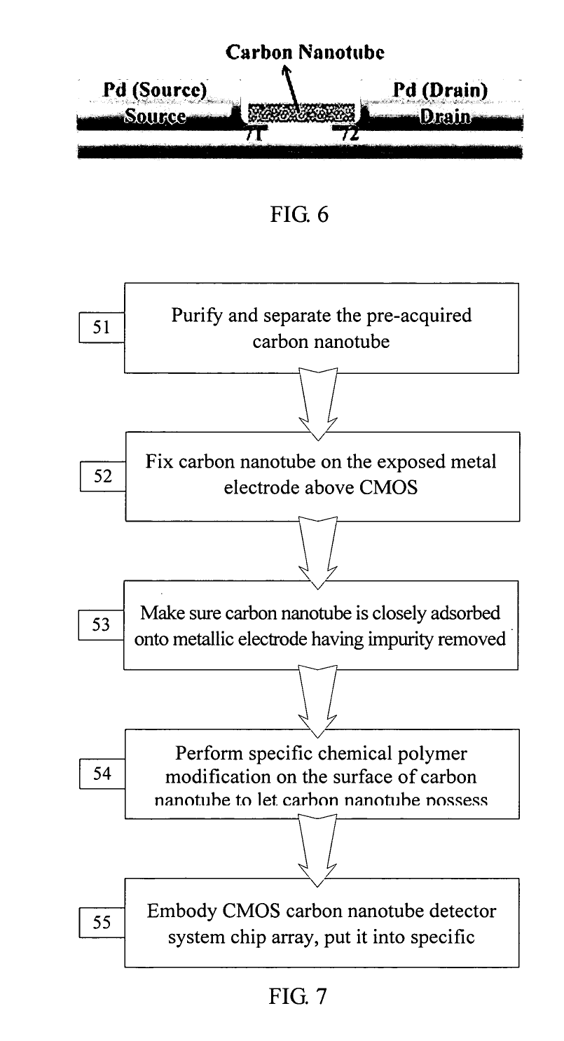

Referring to FIG. 2, DEP force is used in the present invention to separate carbon nanotube first, single-walled and multiple-walled carbon nanotubes are separated, or metal type and semiconductor type carbon nanotubes are separated to facilitate later corresponding application. Purified carbon nanotubes are first immersed in conducting solution 5, drop the solution on top of CMOS. Before the design of CMOS, a needed area above passivation layer is pre-opened above it, then, through the use of microprobe 6 (FIG. 4) (For the probe card, the connections to PCB and other equipments are not fully displayed) of probe card 32, and through the signal generated by function generator 7 (displayed in FIG. 2 but not displayed in FIG. 4) to generate DEP force, and through the adjustment of AC frequency, AC voltage (Peak-to-Peak voltage) and DC voltage, we can then fix the polarized carbon nanotube onto the metal electrode layer, finally, wait for the conducting solution to evaporate and carbon nanotube can then fix well with metal layer. As shown in FIG. 2, when lock-in amplifier 8 is used, at the same time DEP signal is applied, impedance measurement can also be performed, at the same time DEP force is applied, impedance value is measured at any time in order to detect the quantity of carbon nanotube fixed on one pair of electrode pads; additionally, through the use of the concept of Positive DEP and Negative DEP, the extra and non-target number of carbon nanotubes on the electrode are removed by negative DEP force through the adjustment of AC frequency, then a new signal application period is executed again until the required carbon nanotube quantity is achieved, then maintain DEP force until the evaporation of dielectric solution. Additionally, if DEP force is to control carbon nanotube more effectively, this invention further proposes to deposit needle shape metal 61 in front of the electrode layer above CMOS through the use of technologies such as Focused Ion Beam (FIB) and Electron Beam Lithography System, this is as shown in FIG. 5, more concentrated electric field distribution is focused on the tip, this help to ensure the fixing of single carbon nanotube. Additionally, please refer to (Ali Javey, Jing Guo, Qian Wang, Mark Lundstrom & Hongjie Dai. “Ballistic carbon nanotube field-effect transistors”. Nature, Vol. 424, No. 39, p. 654-657, August, 2003), in order to let carbon nanotube have better contact with metallic contact surface and to reduce Schottky Barrier to its lowest value, Palladium (Pd) is thus the best choice. Therefore, here a method based on post process is proposed, it deposits Pd metal on the metallic layer above CMOS structure and has Pd electrode extends forward to form a pair of approaching metallic electrodes 71, 72, then DEP force is applied to fix carbon nanotube on the surface of Pd metal and carbon nanotube transistor of better performance is obtained (as in FIG. 6).

The use of carbon nanotube as molecule detection device has been widely proposed in recent years, generally speaking, they are used in the sensing of biological and gas molecules. After the preparation of CMOS carbon nanotube detector system chip and through specific surface modification of carbon nanotube, we can then obtain CMOS carbon nanotube sensor integration chip with built-in circuit, this is as shown in FIG. 3. As the foreign molecules change, the positive or negative charges of the molecules will react with carrier on carbon nanotube when they get in contact to each other, therefore, the impedance value of the impedance circuit formed by the combination of impedance measurement type carbon nanotube and CMOS will change, or the current passing capability will be reduced due to the formation of a depletion region on the transistor type carbon nanotube or the current passing capability will be enhanced due to more carriers. Furthermore, carbon nanotube is itself a channel for current transfer and is exposed directly to be in contact with foreign matters, we know that this channel is very sensitive to foreign electrons and holes, even tiny change can be detected, therefore, this invention can detect very tiny amount of foreign molecules in fast and accurate way, it can be used as biological sensor, gas sensor, etc.

From the above descriptions, we know that the basic concept for CMOS carbon nanotube detector system chip to detect foreign molecules is to achieve:

1. Different types of foreign molecules will cause obvious difference and distinguishable nature of the carrier change on the channel surface of carbon nanotube wire of the CMOS carbon nanotube system chip.

2. When specific chemical polymer modification is performed on carbon nanotube surface, the carbon nanotube can then detect specific molecule.

3. Through the sensitivity of carbon nanotube on foreign molecules, very tiny amount of molecules can be detected.

4. When carbon nanotube is built on CMOS circuit, no external circuit is needed to judge the measurement results, and a wireless module such as RFID (Radio Frequency Identification) system, can be further installed to achieve the purpose of wireless and remote control.

5. Through the use of array type CMOS carbon nanotube system chip, each measurement carbon nanotube unit is combined with one set of signal computation and processing unit, the measurement time can thus be greatly reduced, moreover, several types of measurement devices can be installed in one chip, the system can thus detect more kinds of foreign molecules.

6. Use “Impedance type measurement system chip” and “transistor type measurement system chip”, we can perform detection effectively on specific molecules.

7. Provide the concept of manipulation of positive and negative DEP, we can complete the mechanism of fixing single or more carbon nanotubes onto the electrode.

A complete preparation method and detection process flow for carbon nanotubes in association with CMOS to form an array type sensor is as shown in FIG. 4 and described as in the followings:

Process 1 51 Purify and separate the pre-acquired carbon nanotube.

Using DEP force to separate carbon nanotube and through the adjustment of AC frequency, AC voltage (Peak-to-Peak voltage) and DC voltage of DEP force, we can separate metallic type and semiconductor type multiple-walled and single-walled carbon nanotube and remove the impurity in the same time, therefore, quite uniform carbon nanotube can be obtained to facilitate later application.

Process 2 52 Fix carbon nanotube on the exposed metal electrode above CMOS.

Immerse purified carbon nanotube into conducting solution and adjust the conductivity of the conducting solution and the concentration of carbon nanotube precisely, then drop the solution onto top part 2 of an upper electrode of exposed metal layer of a pre-designed passivation opening of CMOS chip 1, then provide and generate non-uniform and alternating electric field 7 to the electrode through the use of micro probe 6 of probe card 32 so as to generate DEP force and to manipulate carbon nanotube 4 to be fixed on top of electrode 2. Through the adjustment of carbon nanotube and the concentration of dielectric solution and through the electrode design of small tip and high electric field distribution and through the adjustment of AC frequency, AC voltage (Peak-to-Peak voltage) and DC voltage, we can achieve the goal of single or more carbon nanotubes to set across two electrodes.

Process 3 53 Make sure carbon nanotube is closely adsorbed onto metallic electrode having impurity removed.

Certain period of time after the application of DEP force, use N₂ to blow and dry the liquid on the surface and to remove partial impurity, release DEP force after conducting solution has been evaporated, at this moment, carbon nanotube can be fixed closely on the electrode, use DI water to clean it twice and blow in N₂ to remove impurities on the surface.

Process 4 54 Perform specific chemical polymer modification on the surface of carbon nanotube to let carbon nanotube possess specific detection capability

Carbon nanotube can detect molecules without surface modification mechanism and we can spray the specific chemical polymer we needed on the surface of carbon nanotube through spotting or microspotting to make each set of CMOS carbon nanotube detection chip have the capability to detect specific molecule. In the present invention, microspotting or inkjet head driven by piezoelectric element is used to spray different modification molecules precisely on the surface of carbon nanotube. (Pengfei Qi, Ophir Vermesh, Mihai Grecu, Ali Javey, Qian Wang, and HongjieDai, Shu Peng, K J. Cho, “Towards large arrays of multiplex functionalized carbon nanotube sensors for highly sensitive and selective molecular detection”, NanoLetters, v. 3, p. 347-351, 2003.).

Process 5 55 Embody CMOS carbon nanotube detector system chip array, put it into specific environment for detection.

Since carbon nanotube is built on CMOS integrated circuit, all the signal processing and judgment can be completed by the internal circuit of CMOS. In the present invention, only the signal leads need to be connected out and then CMOS carbon nanotube detector system chip is packaged, one end of carbon nanotube is exposed and placed in different environments for detection. Because this system is of array type, fast and versatile molecule detection capability can thus be achieved; if many combinations are used, a small volume and faster response electronic nose can thus be constructed; meanwhile, RFID can be placed according to the real need so that the user can monitor the system remotely.

CMOS Electronic Circuit

In the electrical current measurement part of transistor, an embodiment of smaller area is proposed in the present invention, please refer to FIG. 7, DC coupling is used for series connection, however, in actual circuit design, since the input trans-impedance is mainly affected by the trans-conductance (g_{mN3} & g_{mP3}) MN3 and MP3 in the feedback loop, and through the adjustment of V_{gsN3} and V_{gsP3} to control the feedback amount, we can change the input trans-impedance in small scale. Therefore, in order to the flexibility during chip test, MPR is connected in series between VDD and MP3, MNR is connected in series between MN3 and GND, MPR and MNR are all designed to work in the triode zone, their roles are like a small resistor, feedback amount is controlled through bias VCP and VCN respectively so as to adjust the input trans-impedance and input resistance to optimum value during the measurement (Ping-Hsing Lu, Chung-Yu Wu, and Ming-Kai Tsai,” Design Techniques for Tunable Transresistance-C VHF Bandpass Filters”, IEEE Journal of Solid-State Circuits, Vol. 29 Issue: 9, pp. 1058-1067 September 1994.).

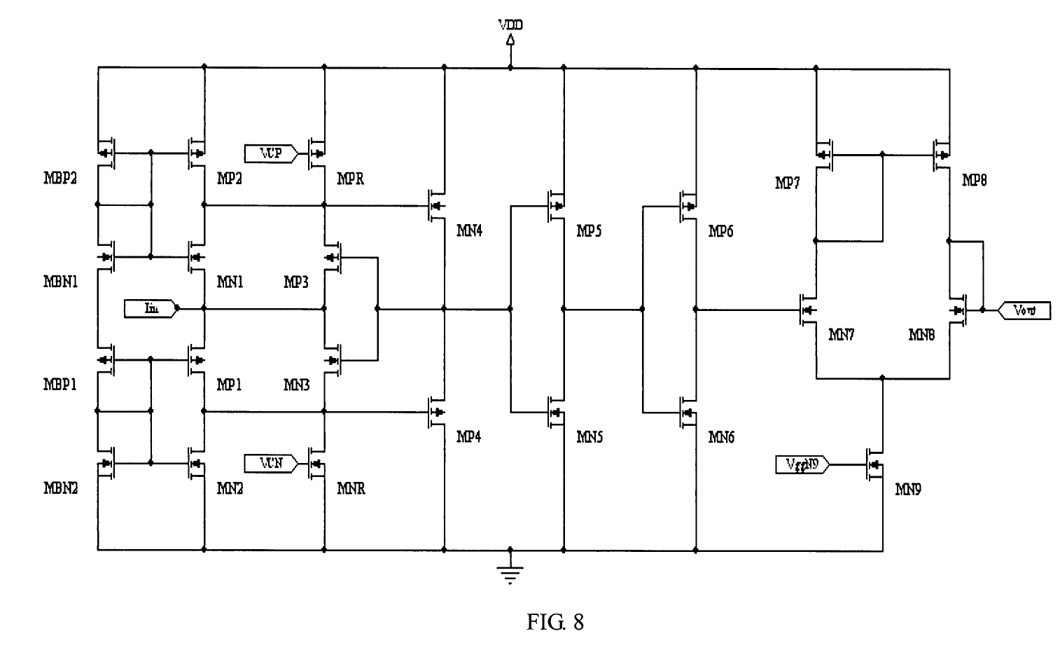

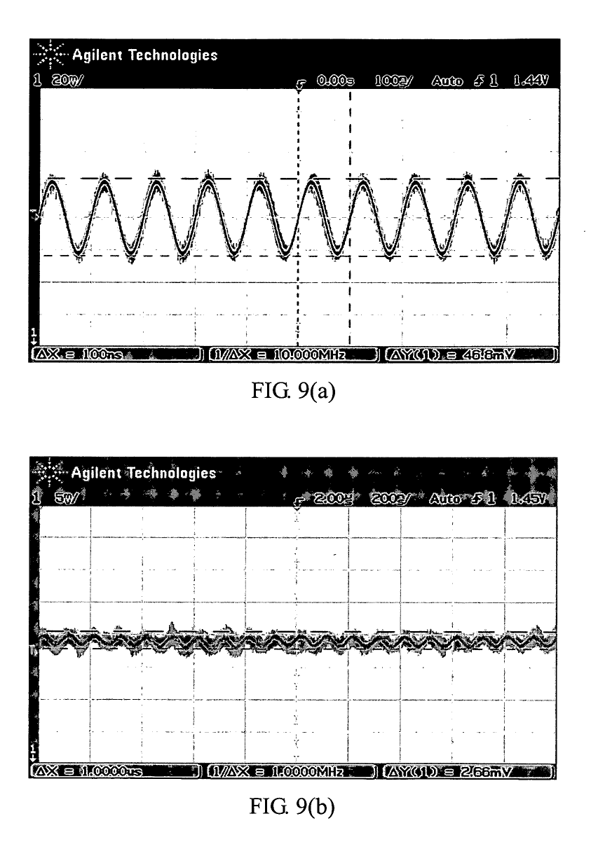

After the application of power and bias to the chip, the input end is a DC voltage of about 1.44V, at this moment, use any waveform generator to input sine wave voltage signal Vᵢₙ and have the signal pass through a precise transistor of 1 MΩ, this is equivalent to an input of sine wave current signal Iᵢₙ=Vᵢₙ/1 MΩ Ampere and at the voltage output end, a DC potential of 1.44V sine wave will be seen. Through the adjustment of Vᵢₙ, the input current is gradually reduced and the circuit characteristic is analyzed through observing the voltage magnitude at the output end. First, sine wave voltage signal of 500 mV and frequency of 10 MHz is used as an input, it is equivalent to an input current of sine wave signal of 500 nA and frequency of 10 MHz, and at the output end, it is a waveform measured by an oscilloscope as shown in FIG. 8(a). Electrical current signal is about 25 nA and the measured output voltage signal is as shown in FIG. 8(b).

Apply appropriate electrical signal to Source(source electrode)→Drain (drain electrode) of carbon nanotube transistor, however, in order to prevent electrochemical reaction being generated on the surface of carbon nanotube under large DC bias, we can apply about −10 mV voltage on Drain (drain electrode) of p-type nano transistor (or a positive bias of 10 mV on the Drain (drain electrode) of n-type nano transistor), then ground the source (source electrode), we expect to measure signal of micron(μA) scale on Source (source electrode)→Drain (drain electrode) end (Please refer to Robert J. Chen, Sarunya Bangsaruntip et al. “Noncovalent functionalization of carbon nanotubes for highly specific electronic biosensors.” 4984-4989 PNAS Apr. 29, 2003 vol. 100, No. 9.); or we can apply an AC signal on Source (source electrode)→Drain (drain electrode) with amplitude of 30 mV and frequency in the range of 20 Hz˜80 Hz so as to be used as the driving voltage of Source (source electrode)˜Drain (drain electrode) of transistor.

In the gate electrode aspect, a negative bias can be added to the back gate electrode of p-type carbon nanotube transistor (the bias can be adjusted according to actual situation), this negative bias is adjusted in the range of 0V˜−3V; in n-type carbon nanotube transistor, positive bias is added to the back gate electrode, this positive bias is adjusted in the range of 0V˜3V, here large bias should be avoided so that the insulated silicon dioxide (SiO₂) will not be penetrated through by electrons and holes which might lead to the damage of the transistor.

### Preferred Embodiments of the Present Invention

### Embodiment 1

The carbon nanotubes used in the current embodiment have a diameter of about 2 nm, most of them are of single-walled semiconductor type. Through the use of vertical type probe card, not only DEP force can be applied, but also the quantity of carbon nanotube above the electrode can be obtained through the measurement of impedance value, therefore, carbon nanotube quantity can be precisely controlled and the assembly between carbon nanotube and CMOS device can reach wafer level. In embodiment 1, CMOS system chip combined with carbon nanotube is designed as “impedance type measurement system chip”, there is no control of back gate electrode, the tiny signal change generated on the carbon nanotube when its surface is in contact with foreign molecules is measured directly by the measurement circuit designed internally in the CMOS device. This impedance type is more suitable for the application of gas sensing because gas molecules are of large quantity. Because there is no back gate electrode design, we can thus design a metal micro heater or polysilicon heater beneath the channel of carbon nanotube, we can also add metal type temperature sensor or semiconductor type semiconductor to increase gas reaction or recovery speed. After the appropriate fixing of carbon nanotube on the electrode, we can also deposit metal electrode above it through the use of post photolithography and process technology so that carbon nanotube can be fastened in more close combination with CMOS chip.

### Embodiment 2

The carbon nanotubes used in the present invention have diameter of about 2 nm, most of them are single-walled semiconductor type. Through the use of vertical type probe card, not only DEP force can be applied, but also the quantity of carbon nanotube above the electrode can be obtained through the measurement of impedance value, therefore, carbon nanotube quantity can be precisely controlled and the assembly between carbon nanotube and CMOS device can reach wafer level. In embodiment 2, CMOS system chip combined with carbon nanotube can be designed as “transistor type measurement system chip”, the via metal beneath metal layer is used as back gate electrode, and through the use of post process, the passivation above via is removed to form a dent, then put a few drops test solution containing biological molecules, based on the concept of the formation of Liquid-Gate by the solution, to control the carrier in the channel of carbon nanotube. In the design of transistor type measurement system chip, the CMOS design rule used in 0.35 μm process of TSMC can be used as CMOS structure; if back gate electrode is to be used more effectively to control carrier flowing situation within carbon nanotube channel, the thickness of dielectric layer must be reduced, at this moment, the MIM (Metal Insulator Metal) process technology provided by TSMC 0.18 μm Mixed Signal 1P6M+MIM Salicide 1.8V/3.3V can be used, metal on the bottom of MIM structure can be used as bottom gate electrode which facilitates the control of carriers within carbon nanotube channel, in this method, no post process is used to remove the passivation layer above back gate electrode but the superiority of ultra thin insulator layer in MIM structure is used to manipulate the carrier flowing situation within carbon nanotube channel. After carbon nanotube is appropriately fixed on the electrode, we can use post photolithography technology to deposit metal electrode above it so that carbon nanotube can be fastened in more close combination with CMOS chip. Additionally, in order to let carbon nanotube have better contact with metallic contact surface and to reduce Schottky Barrier to its lowest value, Palladium (Pd) is thus the best choice. Therefore, here a method based on post process is proposed, it deposits Pd metal on the metallic layer above CMOS structure and has Pd electrode extends forward to form a pair of approaching metallic electrodes, then DEP force is applied to fix carbon nanotube on the surface of Pd metal and carbon nanotube transistor of better performance is obtained.

To summarize the above descriptions for the present invention, we know that CMOS process chip is used together with CMOS-compatible low temperature post process to produce array type carbon nanotube molecular sensor device containing measurement chip. When this chip is applied to the gas detection and biology detection, the detection speed and sensitivity can be effectively enhanced, we thus present this patent application. Any related changes based on what described above, as long as they do not deviate the spirit of the present invention, should all be included in what is claimed of the present invention.

What is claimed is:

1. A method for integrating carbon nanotube and CMOS (Complementary Metal-Oxide Semiconductor) integrated circuit chip having low temperature processes and comprising procedures of:
placing dielectric solution having well dispersed carbon nanotubes on product CMOS chip;
contacting pad pairs connected to CMOS circuit in different areas through the use of probe card, applying in the same time DEP signals for attracting carbon nanotube to pad pairs and performing impedance measurement, detecting the quantity of carbon nanotube fixed on each pair of pads through the measurement of impedance value;
removing extra or non-target quantity of carbon nanotubes by negative DEP force through the adjustment of DC bias, AC voltage and frequency; then a new signal application period is executed again until the required carbon nanotube quantity is reached, then the DEP force is maintained until the dielectric solution is evaporated, through this method, carbon nanotubes can have good contact with each pair of pads.

2. The method of claim 1 wherein tip-like metal can be added in the front end of each pair of pads through the use of focused ion beam (FIB) or electronic beam system, DEP force generates densest electric field at this point so that the fixing of single carbon nanotube above each pair of pads can be more effectively.

3. The method of claim 1 wherein after carbon nanotubes are appropriately fixed on the electrode, the post photolithography technology can also be used to deposit metal electrode on top of them so that carbon nanotubes can be fastened in closer combination with CMOS.

4. A method for integrating carbon nanotube and CMOS (Complementary Metal-Oxide Semiconductor) integrated circuit chip to make it a molecular type sensor array system chip containing signal processing circuit, the method having low temperature processes and comprising procedures of:
placing solution having well dispersed carbon nanotube on the CMOS chip; contacting pad pair connected to CMOS circuit through the use of probe card, in the same time applying DEP signals and performing impedance measurement, detecting the quantity of carbon nanotube fixed on each pair of pads through the measurement of impedance value;
removing extra or non-target quantity of carbon nanotubes by negative DEP force through the adjustment of AC frequency. Then a new signal application period is executed again until the required carbon nanotube quantity is reached, then the DEP force is maintained until the dielectric solution is evaporated, through this method, carbon nanotube can have good contact with each pair of pads.
modifying or functionalizing carbon nanotube surface so that it will have high sensitivity to foreign molecules (gas molecule, biological molecule, etc.) in the environment, then sending the measured signal directly into CMOS signal processor unit connected to each pair of pads, this signal processing unit can be impedance measurement unit, current measurement unit, conductance measurement unit, etc., it can thus directly measure, judge and record measured tiny electrical signal change.

5. The method of claim 4 wherein the surface modification of carbon nanotube is to let specific chemical polymer adhere onto the surface of carbon nanotube, that is to perform specific corresponding molecule modification on carbon nanotube, it can make the chip a versatile sensor system chip for biological molecule and gas molecule, etc.

6. A device for integrating carbon nanotube and CMOS (Complementary Metal-Oxide Semiconductor) integrated circuit chip to make it a molecular type impedance type sensor array system chip containing signal processing unit, the device comprising of:
at least one set of CMOS signal processing unit;
at least one pair of pads to be used as the input end of CMOS signal processing unit;
at least one carbon nanotube installed above each pair of pads and through the contact of each pair of pads by array type probe card, DEP signal is applied and impedance measurement is performed, and the quantity of carbon nanotube fixed on each pair of pads is controlled through the measurement of impedance value;
carbon nanotube surface is modified so that it will have high sensitivity to foreign molecules in the environment (gas molecule, biological molecule, etc.), and the measured signal is sent directly into CMOS signal processor unit connected to each pair of pads, this signal processing unit can be impedance measurement unit, current measurement unit, conductance measurement unit, etc., it can thus directly measure, judge and record measured tiny electrical signal change.

7. The device of claim 6 wherein after carbon nanotubes are fixed appropriately onto the electrode, the photolithography technology used in the post process can be used to deposit metal onto the electrode above carbon nanotubes so that carbon nanotubes can be fastened and have closer combination with the CMOS chip.

8. The device of claim 6 wherein CMOS fabrication process can be used to design a metal micro heater or polysilicon heater carbon beneath nanotube channel.

9. The device of claim 8 wherein CMOS fabrication process can be used to design a metal type temperature sensor or semiconductor type temperature sensor in the neighborhood of metal micro heater or polysilicon heater.

10. A device for integrating carbon nanotube and CMOS (Complementary Metal-Oxide Semiconductor) integrated circuit chip to make it a molecular type transistor type sensor array system chip containing signal processing unit, the device comprising of:
at least one pair of pads is installed on certain metal layer, this is source and drain end respectively;
one via installed beneath the center of each pair of pads and used as back gate, post process is used to remove the passivation above via to form dent, then test solution containing molecules to be detected are dropped on it, the solution is used as a liquid gate to control the carrier within channel of carbon nanotube;
at least one set of CMOS signal processing circuit having its input end connected to source and drain;
at least one carbon nanotube installed on each pair of pads, and through the contact of each pair of pads by array type probe card, DEP signal is applied and impedance measurement is performed, and the quantity of carbon nanotube fixed on each pair of pads is controlled through the measurement of impedance value;
carbon nanotube surface is modified so that it will have high sensitivity to foreign molecules in the environment (gas molecule, biological molecule, etc.), and the measured signal is sent directly into CMOS signal processor unit connected to each pair of pads, this signal processing unit can be impedance measurement unit, current measurement unit, conductance measurement unit, etc., it can thus directly measure, judge and record measured tiny electrical signal change.

11. The device of claim 10 wherein after carbon nanotubes are fixed appropriately onto the electrode, the photolithography technology used in the post process can be used to deposit electrode above carbon nanotubes so that carbon nanotubes can be fastened and have closer combination with the CMOS chip.

12. A device for integrating carbon nanotube and CMOS (Complementary Metal-Oxide Semiconductor) integrated circuit chip to make it a molecular type and transistor type sensor array system chip containing signal processing unit, the device comprising of:
at least one pair of pads installed on the metal layer (CTM) above the insulator dielectric layer of MIM (Metal-Insulator-Metal) structure, they are respectively source and drain pads;
an ultra thin insulator installed on the insulator layer of MIM (Metal-Insulator-Metal) structure;
a back gate installed on the metal at the bottom of MIM structure;
at least one set of CMOS signal processing unit having its input end connected to source and drain;
at least one carbon nanotube installed on each pair of pads, and through the contact of each pair of pads by array type probe card, DEP signal is applied and impedance measurement is performed, and the quantity of carbon nanotube fixed on each pair of pads is controlled through the measurement of impedance value;
carbon nanotube surface is modified so that it will have high sensitivity to foreign molecules in the environment (gas molecule, biological molecule, etc.), and the measured signal is sent directly into CMOS signal processor unit connected to each pair of pads, this signal processing unit can be impedance measurement unit, current measurement unit, conductance measurement unit, etc., it can thus directly measure, judge and record measured tiny electrical signal change.

13. The device of claim 12 wherein after carbon nanotubes are fixed appropriately onto the electrode, the photolithography technology used in the post process can be used to deposit metal onto the electrode above carbon nanotubes so that carbon nanotubes can be fastened and have closer combination with the CMOS chip.
